(19) United States
(12) Patent Application Publication
(10) Pub. No.: US 2020/0270413 A1
(43) Pub. Date: Aug. 27, 2020

(54) LOW LOSS DIELECTRIC COMPOSITE COMPRISING A HYDROPHOBIZED FUSED SILICA

(71) Applicant: ROGERS CORPORATION, Chandler, AZ (US)

(72) Inventors: Thomas A. Koes, Riverside, CA (US); Oscar Ozuna Sanchez, Mesa, AZ (US)

(21) Appl. No.: 16/798,809

(22) Filed: Feb. 24, 2020

Related U.S. Application Data
(60) Provisional application No. 62/811,186, filed on Feb. 27, 2019.

(51) Int. Cl. C08J 5/24; B32B 27/08; H05K 1/03; B32B 27/12; H05K 1/02; B32B 27/04

(52) U.S. Cl. CPC C08J 5/24; B32B 27/08; H05K 1/0373; B32B 27/12; H05K 1/024; B32B 27/04; B32B 2457/00; B32B 2260/021; B32B 2260/046; B32B 2307/204; B32B 2371/00; B32B 2307/3065; B32B 2255/02

(57) ABSTRACT

In an embodiment, a dielectric composite comprises a thermoset derived from a functionalized poly(arylene ether). a triallyl (iso)cyanurate, and a functionalized block copolymer; a hydrophobized fused silica; and a reinforcing fabric. The dielectric composite can be prepared by forming a thermosetting composition comprising the methacrylate functionalized poly(arylene ether), the triallyl (iso)cyanurate, the functionalized block copolymer, the hydrophobized fused silica, an initiator, and a solvent; coating the reinforcing fabric with the thermosetting composition; at least partially curing the thermosetting composition to form a prepreg; and optionally laminating the prepreg and at least one electrically conductive layer to form the circuit material.

### CROSS-REFERENCE TO RELATED APPLICATION

This application claims the benefit of U.S. Provisional Patent Application Ser. No. 62/811,186 filed Feb. 27, 2019. The related application is incorporated herein in its entirety by reference.

### BACKGROUND

High performance circuit applications, where the circuit materials operate at high frequencies or at high data transfer rates, benefit from materials having a low dielectric loss (also referred to as the dissipation loss) and low insertion loss.

The dissipation factor is a measure of loss-rate of energy of an electrical mode of oscillation in a dissipative system. Electrical potential energy is dissipated to some extent in all dielectric materials, usually manifested as heat, and can vary depending on the dielectric material and the frequency of the oscillating electrical signals.

Insertion loss is the loss of signal when traveling into and out of a given circuit or into and out of a given component. Insertion loss is expressed in decibels (dB) or dB per inch and a 3 dB loss is equivalent to the signal strength being reduced by 50%. Insertion loss can vary depending on the dissipation loss of the dielectric, the surface roughness profile of the electrical conductor, and the frequency of the oscillating electrical signals. Induced magnetic fields in the conductor affect the distribution of electrical current forcing it to flow nearer to the surface of the conductor as frequency increases. This phenomenon (also known as the skin-effect) effectively reduces current carrying cross-section. At frequencies ranging from 5 to 100 gigahertz (GHz), the electrical current is forced to travel near the surface of the conductor (0.2 to 1.0 micrometer in depth) having to navigate every peak and valley thereby increasing path length and resistance.

Dissipation loss and insertion loss can be especially relevant to printed circuit board (PCB) antennas, a critical component in any transmission system or wireless communication infrastructure, for example, in cellular base station antennas or in digital applications requiring high data transfer rates. Designing dielectric materials with low dissipation loss is difficult though as modifying one component in a dielectric material to obtain the desired low dissipation loss, often adversely affects other important parameters such as peel strength, flammability rating, thermal and oxidative stability, water absorption, or chemical resistance. Additionally, low insertion loss designs require smoother electrical conductors, especially at high frequencies, tending to reduce peel strength.

In view of the above, there remains a need for improved high performance dielectric composites for use in circuit materials. Specifically, there is a need for circuit materials having an improved combination of properties, including a high peel strength to extremely low profile metal foils, low dissipation loss, and low insertion loss, among other desired electrical, thermal, and physical properties.

### BRIEF SUMMARY

Disclosed herein is a low loss dielectric composite comprising a hydrophobized fused silica.

In an embodiment, a dielectric composite comprises a thermoset derived from a functionalized poly(arylene ether), a triallyl (iso)cyanurate, and a functionalized block copolymer; a hydrophobized fused silica; and a reinforcing fabric.

In an embodiment, a circuit material comprises the dielectric composite and at least one electrically conductive layer.

In an embodiment, the dielectric composite can be prepared by forming a thermosetting composition comprising the methacrylate functionalized poly(arylene ether), the triallyl (iso)cyanurate, the functionalized block copolymer, the hydrophobized fused silica, an initiator, and a solvent; coating the reinforcing fabric with the thermosetting composition; at least partially curing the thermosetting composition to form a prepreg.

The above described and other features are exemplified by the following figures, detailed description, and claims.

### BRIEF DESCRIPTION OF THE DRAWINGS

The following Figures are exemplary embodiments, which are provided to illustrate the present disclosure. The figures are illustrative of the examples, which are not intended to limit devices made in accordance with the disclosure to the materials, conditions, or process parameters set forth herein.

FIG. 1 is a graphical illustration of the relative permittivity (also known as the circuit dielectric constant, Dk) with frequency; and

FIG. 2 is a graphical illustration of the insertion loss with frequency.

### DETAILED DESCRIPTION

Developing a dielectric composite having a good balance of properties is difficult as optimizing one property often results in a different property being adversely affected. For example, using lower polarity polymers that can help to lower the dissipation loss, can increase inherent flammability and adding a flame retardant can adversely affect the electrical properties, thermal stability, water absorption, chemical resistance, or other properties such as peel strength. Likewise, selecting a polymer with a higher glass transition temperature can be at the expense of the desired lower dissipation loss. In addition to considering the properties of the final dielectric material, formulation considerations that affect processing conditions also need to be considered. For example, the minimum melt viscosity (MMV) or resin flow characteristics of a prepreg, both during manufacture and during subsequent lamination, can be important for obtaining good circuit board fabrication performance especially in multi-layered boards (MLBs).

It was surprisingly discovered that a dielectric composite (also referred to herein as the composite) comprising a thermoset derived from a functionalized poly(arylene ether) and a triallyl (iso)cyanurate; a functionalized block copolymer; a hydrophobized fused silica; a ceramic filler other than the hydrophobized fused silica; and a reinforcing fabric (also referred to herein as the fabric) can result in an excellent balance of properties. Specifically, it was discovered that the incorporation of the hydrophobized fused silica is capable of curtailing moisture absorption (imparting hydrophobicity) to the resultant composite thereby maintaining a low dissipation loss (Df) of less than or equal to 0.005 at 10 GHz when exposed to 50% relative ambient humidity. It was also discovered that the incorporation of an additional ceramic filler (for example, hydrophobic fumed silica) is capable of curtailing prepreg resin runback (cascading) during b-staging and that a fine particle size ceramic filler (for example, having a D90 of less than or equal to 2 micrometers) is capable of influencing the lateral resin shear viscosity during lamination and inhibiting resin-filler separation. Still further, it was discovered that the incorporation of the functionalized block copolymer (for example, a carboxylic-acid functionalized block copolymer) is capable of improving the peel strength, even to extremely low profile copper foils, by promoting chemisorption to copper.

The composite comprises a thermoset derived from a functionalized poly(arylene ether) (for example, a methacrylate functionalized poly(arylene ether)) and a triallyl (iso)cyanurate. The thermoset can comprise repeat units derived from other free radically polymerizable monomers, for example, at least one of 1,2-vinyl polybutadiene, polyisoprene, a (meth)acrylate monomer, a styrenic monomer, or a cyclic olefin monomer.

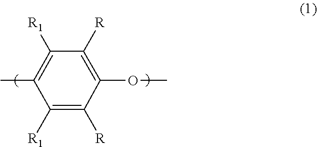

The functionalized poly(arylene ether) comprises repeat units of Formula (1), wherein each R independently is hydrogen, a primary or secondary C₁₋₇ alkyl group, a phenyl group, a C₁₋₇ aminoalkyl group, a C₁₋₇ alkenylalkyl group, a C₁₋₇ alkynylalkyl group, a C₁₋₇ alkoxy group, a C₆₋₁₀ aryl group, or C₆₋₁₀ aryloxy group and each R₁ independently is hydrogen or methyl. Each R independently can be a C₁₋₇ or C₁₋₄ alkyl or phenyl.

The poly(arylene ether) can comprise at least one of poly(2,6-dimethyl-1,4-phenylene ether), poly(2,6-diethyl-1,4-phenylene ether), poly(2,6-dipropyl-1,4-phenylene ether), poly(2-methyl-6-allyl-1,4-phenylene ether), poly(2,6-diallyl-1,4-phenylene ether), poly(di-tert-butyl-dimethoxy-1,4-phenylene ether), poly(2,6-dichloromethyl-1,4-phenylene ether, poly(2,6-dibromomethyl-1,4-phenylene ether), poly(2,6-di(2-chloroethyl)-1,4-phenylene ether), poly(2,6-ditolyl-1,4-phenylene ether), poly(2,6-dichloro-1,4-phenylene ether), or poly(2,6-diphenyl-1,4-phenylene ether). The poly(arylene ether) can comprise 2,6-dimethyl-1,4-phenylene ether units, optionally with 2,3,6-trimethyl-1,4-phenylene ether units.

The functionalized poly(arylene ether), for example, poly(phenylene ether), comprises a functional group containing at least one terminal ethylenically unsaturated double bond. For example, the functional group of the functionalized poly(arylene ether) can comprise at least one of a vinyl group, an allyl group, an alkyne group, a (meth)acrylate group, a cyclic olefin, or a maleinate group. Specifically, the functionalized poly(arylene ether) can comprise a dimethacrylate poly(phenylene ether) such as that of Formula (I), wherein Y is a divalent linking group.

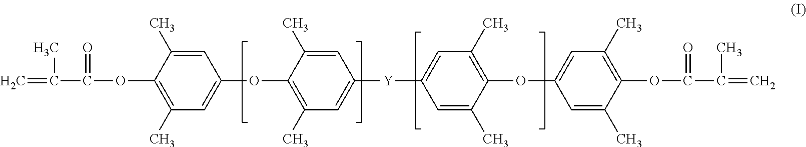

The functional group can optionally further comprise at least one of a carboxy group (for example, a carboxylic acid), an anhydride, an amide, an amine, an ester, or an acid halide. The polyfunctional compounds that can provide a carboxylic acid functional group can include at least one of maleic acid, maleic anhydride, fumaric acid, or citric acid.

The functionalized poly(arylene ether) can have a number average molecular weight of 500 to 4,000 Daltons (Da), or 500 to 3,000 Da, or 1,000 to 2,000 Da based on polystyrene standards.

Examples of functionalized poly(arylene ether) oligomers include MGC OPE-2St formerly produced by Mitsubishi Gas, SA9000 and SA5587 commercially available from SABIC Innovative Plastics, XYRON-modified polyphenylene ether polymers commercially available from Asahi Kasei.

The triallyl (iso)cyanurate comprises at least one of triallyl isocyanurate and triallyl cyanurate as illustrated in Formula (2A) and Formula (2B), respectively.

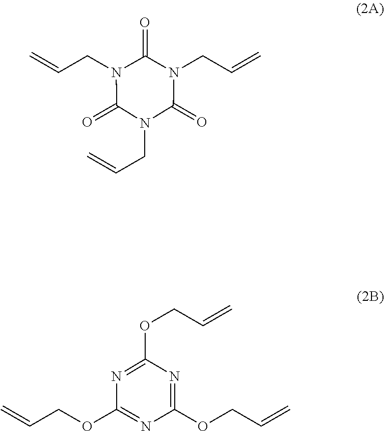

The thermoset can be derived from a thermosetting composition comprising 40 to 60 weight percent (wt %) of the functionalized poly(arylene ether) based on the total weight of the thermosetting components (for example, the functionalized poly(arylene ether) the triallyl (iso)cyanurate, and the functionalized block copolymer). The thermoset can be derived from a thermosetting composition comprising 35 to 60 wt %, or 35 to 45 wt % of the triallyl (iso)cyanurate based on the total weight of the thermosetting components. The thermoset can be derived from a thermosetting composition comprising 0.1 to 10 wt %, or 0.5 to 5 wt %, or 2 to 5 wt % of the functionalized block copolymer based on the total weight of the thermosetting components. The thermosetting composition can comprise 5 to 30 wt %, or 15 to 23 wt %, or 15 to 20 wt % of the triallyl (iso)cyanurate based on the total weight of the thermosetting composition minus the fabric or any solvent. The composite can comprise 25 to 60 wt %, or 35 to 50 wt % of the thermoset based on the total weight of the composite minus the fabric.

The composite comprises a hydrophobized fused silica. The hydrophobized fused silica can be formed by grafting a hydrophobic compound onto the fused silica. The hydrophobic compound can comprise at least one of a phenyl silane or a fluorosilane. The phenyl silane can comprise at least one of p-chloromethyl phenyl trimethoxy silane, phenyl trimethoxy silane, phenyl triethoxy silane, phenyl trichlorosilane, phenyl-tris-(4-biphenylyl)silane, (phenoxy) triphenyl silane, or a functionalized phenyl silane. The functionalized phenyl silane can have the formula R′SiZ¹R²Z² wherein R′ is alkyl with 1 to 3 carbon atoms, —SH, —CN, —N₃ or hydrogen; Z¹ and Z² are each independently chlorine, fluorine, bromine, alkoxy with not more than 6 carbon atoms, NH, —NH₂, —NR₂′; and R² is

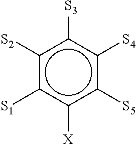

wherein each of the S-substituents, S₁, S₂, S₃, S₄ and S₅ are independently hydrogen, alkyl with 1 to 4 carbon atoms, methoxy, ethoxy, or cyano, provided that at least one of the S-substituents is other than hydrogen, and when there is a methyl or methoxy S-substituent, then (i) at least two of the S-substituents are other than hydrogen, (ii) two adjacent S-substituents form with the phenyl nucleus a naphthalene or anthracene group, or (iii) three adjacent S-substituents form together with the phenyl nucleus a pyrene group, and X is the group —(CH₂)ₙ—, wherein n is 0 to 20, or 10 to 16 when n is not 0, in other words, X is an optional spacer group. The term “lower” in connection with groups or compounds, means 1 to 7 and, or 1 to 4 carbon atoms.

The hydrophobic compound can comprise a fluorosilane. The fluorosilane can be beneficial as compared to other hydrophobic silanes as the fluorine atom has the lowest polarizability of all the atoms and fluorinated molecules therefore exhibit very weak intermolecular dispersion forces. As a result, fluorinated molecules are remarkably both hydrophobic and oleophobic at the same time. In order to take full advantage of the hydrophobizing potential of fluorinated compounds in the composite, the fused silica can be pre-treated with a fluorinated silane prior to forming the composite instead of performing an in-situ silanization of the fused silica in a composite. Pre-treating the fused silica can be preferential due to the oleophobicity (immiscibility) of the fluorinated silane in the composite. It is noted that just as it can be beneficial to pre-treat the fused silica with a fluorinated silane prior to forming the composite, it can likewise be beneficial to pre-treat the fused silica with other hydrophobic silanes.

The fluorosilane coating can be formed from a perfluorinated alkyl silane having the formula: CF₃(CF₂)ₙ—CH₂CH₂SiX, wherein X is a hydrolyzable functional group and n=0 or a whole integer. The fluorosilane can comprise at least one of (3,3,3-trifluoropropyl)trichlorosilane, (3,3,3-trifluoropropyl)dimethylchlorosilane, (3,3,3-trifluoropropyl)methyldichlorosilane, (3,3,3-trifluoropropyl)methyldimethoxysilane, (tridecafluoro-1,1,2,2-tetrahydrooctyl)-1-trichlorosilane, (tridecafluoro-1,1,2,2-tetrahydrooctyl)-1-methyldichlorosilane, (tridecafluoro-1,1,2,2-tetrahydrooctyl)-1-dimethylchlorosilane, (heptadecafluoro-1,1,2,2-tetrahydrodecyl)-1-methyldichlorosilane, (heptadecafluoro-1,1,2,2-tetrahydrodecyl)-1-trichlorosilane, heptadecafluoro-1,1,2,2-tetrahydrodecyl)-1-dimethylchlorosilane, (heptafluoroisopropoxy) propylmethyl dichlorosilane, 3-(heptafluoroisopropoxy) propyltrichlorosilane, 3-(heptafluoroisopropoxy) propyltriethoxysilane, or perfluorooctyltriethoxysilane. The fluorosilane can comprise perfluorooctyltriethoxysilane.

Other silanes can be used instead of, or in addition to, the phenylsilane and the fluorosilane, for example, aminosilanes and silanes containing polymerizable functional groups such as acryl and methacryl groups. Examples of aminosilanes include at least one of N-methyl-γ-aminopropyltriethoxysilane, N-ethyl-γ-aminopropyltrimethoxysilane, N-methyl-β-aminoethyltrimethoxysilane, γ-aminopropylmethyldimethoxysilane, N-methyl-γ-aminopropylmethyldimethoxysilane, N-(β-N-methylaminoethyl)-γ-aminopropyl triethoxysilane, N-(γ-aminopropyl)-γ-aminopropylmethyldimethoxysilane, N-(γ-aminopropyl)-N-methyl-γ-aminopropylmethyldimethoxysilane and γ-aminopropylethyldiethoxysilaneaminoethylamino trimethoxy silane, aminoethylamino propyl trimethoxy silane, 2-ethylpiperidinotrimethylsilane, 2-ethylpiperidinodimethylhydridosilane, 2-ethylpiperidinomethylphenylchlorosilane, 2-ethylpiperidinodicyclopentylchlorosilane, (2-ethylpiperidino) (5-hexenyl)methylchlorosilane, morpholinovinylmethylchlorosilane, or n-methylpiperazinophenyldichlorosilane.

Silanes including a polymerizable functional group include silanes of the formula R^{a}ₓSiR^{b}₍₃₋ₓ₎R, in which each R^{a} is the same or different (for example, the same) and is halogen (for example, Cl or Br), C₁₋₄ alkoxy (for example, methoxy or ethoxy), or C₂₋₆ acyl; each R^{b} is a C₁₋₈ alkyl or C₆₋₁₂ aryl (for example, R^{b} can be methyl, ethyl, propyl, butyl or phenyl); x is 1, 2, or 3 (for example, 2 or 3); and R is —(CH₂)ₙ—OC(═O)C(R^{c})═CH₂, wherein R^{c} is hydrogen or methyl and n is an integer 1 to 6, or, 2 to 4. The silane can comprise at least one of methacrylsilane(3-methacryloxypropyl trimethoxy silane) or trimethoxyphenylsilane.

The hydrophobized fused silica can have a D90 particle size of 1 to 20 micrometers, or 5 to 15 micrometers. As used herein, the particle size can be determined using dynamic light scattering and the D90 refers to 90% by volume of the particles having a particle size below the number. The composite can comprise 20 to 60 wt %, or 35 to 50 wt %, or 35 to 40 wt % of the hydrophobized fused silica based on the total weight of the composite minus the fabric.

The composite comprises a functionalized block copolymer. The functionalized block copolymer comprises a first block, a second block compositionally different from the first block, and optionally additional blocks. The first block can be derived from at least one of styrene or a para-substituted styrene monomer (for example, methylstyrene, para-ethylstyrene, para-n-propylstyrene, para-iso-propylstyrene, para-n-butylstyrene, para-sec-butylstyrene, para-iso-butylstyrene, para-t-butylstyrene, an isomer of para-decylstyrene, or an isomer of para-dodecylstyrene). The second block can comprise repeat units derived from a conjugated diene, for example, least one of isoprene or 1,3-butadiene. Additionally, the second block can comprise repeat units present in the first block.

The functionalized block copolymer can optionally comprise repeat units derived from at least one of ethylene, an alpha olefin having of 3 to 18 carbon atoms (for example, propylene), a 1,3-cyclodiene monomer, a monomer of a conjugated diene having a vinyl content less than 35 mole percent prior to hydrogenation, acrylonitrile, or an (meth)acrylic ester. These optional repeat units can be present in one or both of the first block or the second block. These optional repeat units can be present in a third block. The (meth)acrylic ester can comprise at least one of methyl methacrylate, ethyl methacrylate, propyl methacrylate, n-butyl methacrylate, isobutyl methacrylate, hexyl methacrylate, 2-ethylhexyl methacrylate, dodecyl methacrylate, lauryl methacrylate, methoxyethyl methacrylate, dimethylaminoethyl methacrylate, diethylaminoethyl methacrylate, glycidyl methacrylate, trimethoxysilylpropyl methacrylate, trifluoromethyl methacrylate, trifluoroethyl methacrylate, tert-butyl methacrylate, isopropyl methacrylate, cyclohexyl methacrylate, isobornyl methacrylate, methyl acrylate, ethyl acrylate, propyl acrylate, n-butyl acrylate, isobutyl acrylate, hexyl acrylate, 2-ethylhexyl acrylate, dodecyl acrylate, lauryl acrylate, methoxyethyl acrylate, dimethylaminoethyl acrylate, diethylaminoethyl acrylate, glycidyl acrylate, trimethoxysilylpropyl acrylate, trifluoromethyl acrylate, trifluoroethyl acrylate, isopropyl acrylate, cyclohexyl acrylate, isobornyl acrylate, or tert-butyl acrylate.

The functionalized block copolymer can be functionalized by grafting a monomer onto the back bone of the block copolymer. The grafting monomer can comprise at least one of an unsaturated monomer having one or more saturated groups or a derivative thereof. The functionalized block copolymer can comprise a carboxylic acid functionalized block copolymer. The grafting monomer can comprise at least one of a monocarboxylic acid compound or a polycarboxylic acid compound, such as maleic acid or a derivative such as maleic anhydride. The grafting monomer can comprise at least one of maleic acid, fumaric acid, itaconic acid, citraconic acid, acrylic acid, an acrylic polyether, an acrylic anhydride, methacrylic acid, crotonic acid, isocrotonic acid, mesaconic acid, angelic acid, maleic anhydride, itaconic anhydride, or citraconic anhydride. The grafting monomer can comprise at least one of maleic acid or maleic anhydride.

The functionalized block copolymer can have a carboxylic acid number of 10 to 50, or 28 to 40 milliequivalents KOH per gram (meq KOH/g). The functionalized block copolymer can have a number average molecular weight of 1,000 to 20,000 Da, or 8,000 to 15,000 Da based on polystyrene standards. The functionalized block copolymer can have a first block content of 10 to 50 wt %, or 15 to 30 wt % based on the total weight of the functionalized block copolymer.

The composite can comprise a ceramic filler other than the hydrophobized fused silica. The ceramic filler can comprise at least one of fumed silica, titanium dioxide, barium titanate, strontium titanate, corundum, wollastonite, Ba₂Ti₉O₂₀, hollow ceramic spheres, boron nitride, aluminum nitride, silicon carbide, beryllia, alumina, alumina trihydrate, magnesia, mica, talc, nanoclay, or magnesium hydroxide. The composite can comprise at least one of solid glass spheres, hollow glass spheres, or core shell rubber spheres. The ceramic filler can have a D90 particle size of 0.1 to 10 micrometers, or 0.5 to 5 micrometers. The ceramic filler can have a D90 particle size of less than or equal to 2 micrometers, or 0.1 to 2 micrometers. The ceramic filler can be present in an amount of 0.1 to 10 wt %, or 0.1 to 5 wt % based on the total weight of the composite minus the fabric.

The composite can comprise a hydrophobic fumed silica. The hydrophobic fumed silica can be present in an amount of 0.1 to 5 wt %, or 1 to 5 wt % based on the total weight of the composite minus the fabric. The hydrophobic fumed silica can have a Brunauer, Emmett, and Teller (BET) surface area of 10 to 500 meters squared per gram (m²/g), or 50 to 350 m²/g, or 100 to 200 m²/g, or 145 to 155 m²/g. An example of a commercially available dimethyl functionalized hydrophobic fumed silica is AEROSIL™ R-972 commercially available from Evonik.

The hydrophobic fumed silica can comprise a methacrylate functionalized fumed silica that comprises a methacrylate functional group. For example, the fumed silica can be functionalized with a compound comprising a methacrylate functional group to form the methacrylate functionalized fumed silica. The methacrylate functional hydrophobic fumed silica can enhance the thermal and mechanical properties of the resulting composite by participating in the polymerization of the thermosetting composition. The fumed silica functionalizing compound can comprise a methacrylsilane (for example, γ-methacryloxypropyl methyldimethoxy silane, γ-methacryloxypropyl trimethoxy silane, γ-methacryloxypropyl methyldiethoxy silane, or γ-methacryloxypropyl triethoxy silane). The fumed silica can optionally comprise octyl functional groups derived from octyltrimethoxysilane or dimethyl functional groups derived from dimethyldichlorosilane. An example of a commercially available methacrylate functionalized hydrophobic fumed silica is AEROSIL™ R-711 commercially available from Evonik.

The composite can comprise titanium dioxide. The titanium dioxide can have a D90 particle size of 0.1 to 10 micrometers, or 0.5 to 5 micrometers. The titanium dioxide can have a D90 particle size of less than or equal to 2 micrometers, or 0.1 to 2 micrometers. The titanium dioxide can be present in an amount of 0.1 to 10 wt %, or 0.1 to 5 wt % based on the total weight of the composite minus the fabric. A weight ratio of the hydrophobic fumed silica to the titanium dioxide can be 1:2 to 2:1.

The composite can optionally comprise a flame retardant. The composite can comprise 1 to 15 wt %, or 5 to 10 wt % of the flame retardant based on the total weight of the composite minus the fabric. The flame retardant can comprise a metal hydrate, having, for example, a volume average particle diameter of 1 to 500 nanometers (nm), or 1 to 200 nm, or 5 to 200 nm, or 10 to 200 nm; alternatively the volume average particle diameter can be 500 nm to 15 micrometers, for example, 1 to 5 micrometers. The metal hydrate can comprise a hydrate of a metal, for example, at least one of Mg, Ca, Al, Fe, Zn, Ba, Cu, or Ni. Hydrates of Mg, Al, or Ca can be used, for example, at least one of aluminum hydroxide, magnesium hydroxide, calcium hydroxide, iron hydroxide, zinc hydroxide, copper hydroxide, nickel hydroxide, or hydrates of calcium aluminate, gypsum dihydrate, zinc borate, zinc stannate, or barium metaborate. Composites of these hydrates can be used, for example, a hydrate containing Mg and at least one of Ca, Al, Fe, Zn, Ba, Cu, or Ni. A composite metal hydrate can have the formula MgMₓ(OH)_{y} wherein M is Ca, Al, Fe, Zn, Ba, Cu, or Ni, x is 0.1 to 10, and y is 2 to 32. The flame retardant particles can be coated or otherwise treated to improve dispersion and other properties. The composite can optionally comprise organic halogenated flame retardants such as hexachloroendomethylenetetrahydrophthalic acid (HET acid), tetrabromophthalic acid, or dibromoneopentyl glycol. The composite can optionally comprise a halogen-free flame retardant (such as melamine cyanurate), a phosphorus-containing compound (such as a phosphinate, a diphosphinate, a phosphazene, a phosphonate, a fine particle size melamine polyphosphate, or a phosphate), a polysilsesquioxane, or a siloxane.

The flame retardant can comprise a brominated flame retardant. The brominated flame retardant can comprise at least one of bis-pentabromophenyl ethane, ethylene bistetrabromophthalimide, tetradecabromodiphenoxy benzene, or decabromodiphenyl oxide. The flame retardant can be used in combination with a synergist, for example, a halogenated flame retardant can be used in combination with a synergists such as antimony trioxide. The composite of can comprise 1 to 15 wt %, or 5 to 10 wt % of brominated flame retardant based on the total weight of the composite minus the fabric.

The composite comprises a fabric, for example, a fibrous layer comprising a plurality of thermally stable fibers. The fabric can be woven or non-woven, such as a felt. The fabric can reduce shrinkage of the composite upon cure within the plane of the composite. In addition, the use of the fabric can help render the composite with a relatively high dimensional stability and mechanical strength (modulus). Such materials can be more readily processed by methods in commercial use, for example, lamination, including roll-to-roll lamination. The thermally stable fibers can comprise glass fibers such as at least one of E glass fibers, S glass fibers, D glass fibers, or lower dielectric constant, lower dissipation loss fibers such as L glass fibers or quartz fibers. For example, lower dielectric constant, lower dissipation factor, thermally stable fibers such as NITTOBO NE commercially available from Nitto Bosch Co., Ltd. of Tokyo, Japan or L glass fiber commercially available from AGY, Aiken, S.C. Thermally stable fabrics comprising glass fibers can be plain weave or spread-weave and can be balanced. Spread-weaves can enhance impedance control, resistance to conductive anodic filament (CAF) growth, dimensional stability, prepreg yields and can be more amenable to laser drilling during circuit fabrication. The fabric can comprise a lower dielectric constant, lower dissipation factor spread-weave fabric in an amount of 5 to 40 wt %, or 15 to 25 wt % based on the total weight of the composite.

The thermally stable fibers can comprise polymer-based fibers such as high temperature polymer fibers, pulp or fibrillated pulp. The polymer-based fibers can comprise a liquid crystal polymer such as VECTRAN™ commercially available from Kuraray America Inc., Fort Mill, S.C. The polymer-based fibers can comprise at least one of polyetherimide (PEI), polyether ketone (PEK), polyether ether ketone (PEEK), polysulfone (PSU), polyethersulfones (PES or PESU), polyphenylene sulfide (PPS), polycarbonate (PC), poly m-aramid (fibers or fibrids), poly p-aramid, polyvinylidene difluoride (PVDF) or polyester (such as PET). The fabric can have a thickness of 5 to 100 micrometers, or 10 to 60 micrometers. The composite can comprise the fabric in an amount of 5 to 40 wt %, or 15 to 25 wt % based on the total weight of the composite.

The dielectric composite can comprise the thermoset derived from the functionalized poly(arylene ether) and the triallyl (iso)cyanurate; the functionalized block copolymer; the hydrophobized fused silica; and the fabric. The functionalized poly(arylene ether) can have a number average molecular weight of 500 to 3,000 Daltons, or 1,000 to 2,000 Daltons based on polystyrene standards. The thermoset can be derived from a thermosetting composition comprising 40 to 60 wt % of the functionalized poly(arylene ether) based on the total weight of the thermosetting components. The dielectric composite can comprise 25 to 60 wt % of the thermoset based on the total weight of the dielectric composite minus the reinforcing fabric.

The thermoset can be derived from a thermosetting composition comprising 0.1 to 10 wt % of the functionalized block copolymer based on the total weight of the thermosetting components. At least one of the functionalized block copolymer can comprise a maleinized styrenic block copolymer or the functionalized poly(arylene ether) can comprise a methacrylate functionalized poly(arylene ether). The functionalized styrenic block copolymer can have a carboxylic acid number of 10 to 50, or 28 to 40 milliequivalents KOH per gram. The functionalized styrenic block copolymer can have a carboxylic acid number of 10 to 50, or 28 to 40 meq KOH/g. The functionalized styrenic block copolymer can have a number average molecular weight of 1,000 to 20,000 Da based on polystyrene standards. The functionalized styrenic block copolymer can have a styrene content of 10 to 50 wt % based on the total weight of the functionalized styrenic block copolymer.

The dielectric composite can comprise 20 to 60 weight percent of the hydrophobized fused silica based on the total weight of the dielectric composite minus the reinforcing fabric. The hydrophobized fused silica can comprise a surface treatment derived from at least one of a phenyl silane or a fluorosilane. The hydrophobized fused silica can have a D90 particles size of 1 to 20 micrometers.

The dielectric composite can further comprise a ceramic filler other than the hydrophobized fused silica. The ceramic filler can comprise at least one of fumed silica, titanium dioxide, barium titanate, strontium titanate, corundum, wollastonite, Ba₂Ti₉O₂₀, hollow ceramic spheres, boron nitride, aluminum nitride, silicon carbide, beryllia, alumina, alumina trihydrate, magnesia, mica, talc, nanoclay, or magnesium hydroxide. The ceramic filler can comprise a hydrophobic fumed silica. The hydrophobic fumed silica can comprise a methacrylate functionalized hydrophobic fumed silica. The dielectric composite can comprise 0.1 to 5 wt % of the hydrophobic fumed silica based on the total weight of the dielectric composite minus the reinforcing fabric. The hydrophobic fumed silica can comprise a surface treatment derived from 2-propenoic acid, 2-methyl-, 3-(trimethoxysilyl)propylester. The hydrophobic fumed silica can have a BET surface area of 100 to 200 m²/g. The ceramic filler can comprise titanium dioxide. The dielectric composite can comprise 0.1 to 10 wt % of the titanium dioxide based on the total weight of the dielectric composite minus the optional reinforcing fabric. The ceramic filler can have a D90 particle size of 0.5 to 10 micrometers. The ceramic filler can comprise a hydrophobic fumed silica and titanium dioxide and a weight ratio of the hydrophobic fumed silica to the titanium dioxide can be 1:2 to 2:1.

The dielectric composite can comprise a flame retardant. The dielectric composite can comprise 1 to 15 wt % of the flame retardant based on the total weight of the dielectric composite minus the reinforcing fabric. The dielectric composite can comprise the reinforcing fabric in an amount of 5 to 40 wt % based on the total weight of the dielectric composite. The reinforcing fabric can comprise at least one of L glass fibers or quartz fibers. The reinforcing fabric can be a spread-weave reinforcing fabric that is present in an amount of 5 to 40 wt % based on the total weight of the dielectric composite. The dielectric composite can be a prepreg having a thickness of 1 to 1,000 micrometers wherein the thermoset is only partially cured.

A prepreg can be formed by treating the fabric with a thermosetting composition comprising the functionalized poly(arylene ether), the triallyl (iso)cyanurate, the functionalized block copolymer, the hydrophobized fused silica, an initiator, and optionally a solvent; and partially curing (b-staging) the thermosetting composition. As used herein, the term b-staging can refer to: (1) the thermosetting composition optionally present in a solvent carrier being (2) applied to a surface, for example, a woven fiberglass, followed by (3) evaporation of the optional solvent carrier below the onset temperature for polymerization to occur followed by (4) further application of heat in order to (5) partially polymerize (or partially cure) the thermosetting composition followed by (6) cooling so as to not completely polymerize the thermosetting composition. Partially curing the thermosetting composition can be particularly useful for applications where it is important to regulate the amount of resin flow that occurs when heat and pressure are applied to the b-staged system. Subsequent to forming the b-staged system, the b-staged system can be exposed to an additional heat and the partially cured thermosetting composition can be fully cured. This final polymerization is often referred to as c-staging. Examples of forming a composite via a partially cured composite include first manufacturing a b-staged thermosetting composition (otherwise known as a prepreg) and then either laminating the prepreg in the same facility to form a c-staged laminate or laminating the prepreg in a different facility. Lamination usually comprises the application of both heat and pressure and can form multilayer structures.

The thermosetting composition can be formed by combining the various components, in any order, optionally in the melt or in an inert solvent. The combining can be by any suitable method, such as blending, mixing, or stirring. The components used to form the thermosetting composition can be combined by dissolving or suspending the component in a solvent to provide a coating mixture or solution. The forming of the prepreg can comprise holding the treated fabric at an elevated temperature for a sufficient time to volatilize the formulation solvent(s) and at least partially cure (b-stage) the thermosetting composition. After forming the prepreg, the prepreg can be stored for a period of time prior to fully curing the material during the manufacture, for example, of a circuit laminate or other circuit subassembly. In one type of construction, multilayer laminates can comprise two or more plies of the prepreg between electrically conductive layers.

The initiator can thermally decompose to form free radicals, which then initiate polymerization of ethylenically unsaturated double bonds within the formulation. These initiators generally provide weak bonds, for example, bonds that have small dissociation energy. The free-radical initiator can comprise at least one of a peroxide initiator, an azo initiator, a carbon-carbon initiator, a persulfate initiator, a hydrazine initiator, a hydrazide initiator, a benzophenone initiator, or a halogen initiator. The initiator can comprise 2,3-dimethyl-2,3-diphenylbutane, 3,4-dimethyl-3,4-diphenylhexane, or poly(1,4-diisopropylbenzene). The initiator can comprise an organic peroxide, for example, at least one of dicumyl peroxide, t-butylperbenzoate, α,α′-di-(t-butyl peroxy) diisopropylbenzene, or 2,5-dimethyl-2,5-di(t-butylperoxy)-3-hexyne. Optionally, the initiator can be light sensitive comprising, for example, α-hydroxy ketone, phenylglyoxylate, benzyldimethyl-ketal, α-amino ketone, monoacyl phosphine (MAPO), bisacyl phosphine (BAPO), phosphine oxides or metallocenes. The initiator can be present in an amount of 0.1 to 5 wt %, or 0.1 to 1.5 wt % based on the total weight of the thermosetting composition.

The solvent can be selected so as to dissolve the thermosetting components, disperse particulate additives and any other optional additives that can be present, and to have a convenient evaporation rate for forming, drying, and b-staging. The solvent can comprise at least one of xylene, toluene, methyl ethyl ketone (MEK), methyl isobutyl ketone (MIBK), hexane, a higher liquid linear alkane (for example, heptane, octane, or nonane), cyclohexane, cyclohexanone, isophorone, glycol ether PM, glycol ether PM acetate, or a terpene-based solvent. The solvent can comprise at least one of xylene, toluene, methyl ethyl ketone, methyl isobutyl ketone or hexane. The solvent can comprise at least one of xylene or toluene. The solvent can be present in an amount of 2 to 20 wt %, or 2 to 10 wt %, or 2 to 5 wt % based on the total weight of the thermosetting composition. The thermosetting composition can comprise 80 to 98 wt % solids (all components other than the solvent), or 15 to 40 wt % solids, based on the total weight of the thermosetting composition.

The method for treating the fabric with the thermosetting composition is not limited and can be performed, for example, by dip coating or roll coating, optionally at an increased temperature. A single ply prepreg can have a thickness of 10 to 200 micrometers, or 30 to 150 micrometers. It is noted that if a single ply, unclad material is desired, then the thermosetting composition can be fully cured to form the composite.

Two or more prepregs can be laminated together to form the composite material. A circuit material comprising the composite can likewise be formed by laminating at least one ply of the prepreg and at least one electrically conductive layer.

The laminating can entail laminating a layered structure comprising a dielectric stack of one or more prepregs, an electrically conductive layer, and an optional intermediate layer between the dielectric stack and the electrically conductive layer to form the laminate. Likewise, the layered structure can comprise the dielectric stack without the electrically conductive layer if so desired. The electrically conductive layer can be in direct contact with the dielectric stack, without the intermediate layer. The dielectric stack can comprise 1 to 200 plies, or 2 to 50 plies, or 5 to 100 plies and at least one electrically conductive layer can be located on an outer most side of the dielectric stack. The layered structure can then be placed in a press, e.g., a vacuum press, under a pressure and temperature and for duration of time suitable to bond the layers, forming the laminate. Optionally, the layered structure can be roll-to-roll laminated or autoclaved.

Lamination and optional curing can be by a one-step process, for example, using a vacuum press, or can be by a multi-step process. In a one-step process, the layered structure can be placed in a press, brought to a laminating pressure and heated to a laminating temperature. The laminating temperature can be 100 to 390 degrees Celsius (° C.), or 100 to 250° C., or 100 to 200° C., or 100 to 175° C., or 150 to 170° C. The laminating pressure can be 1 to 3 megapascal (MPa), or 1 to 2 MPa, or 1 to 1.5 MPa. The laminating temperature and pressure can be maintained for a desired dwell (soak) time, for example, 5 to 150 minutes, or 5 to 100 minutes, or 10 to 50 minutes, and thereafter cooled, at a controlled cooling rate (with or without applied pressure), for example, to less than or equal to 150° C.

It was surprisingly discovered that by altering the lamination parameters, for example, the temperature, dwell (soak) time and pressure, that the resultant properties of the laminate could be modified. Without intending to be bound by theory, it is proposed that a standard epoxy cure cycle (using a lamination temperature of 180 to 200° C. and a dwell (soak) time of 90 minutes and a pressure of 1.6 to 2.1 MPa) imparts an energy profile better suited for thermodynamic reaction control. When the imparted temperature, dwell time (soak) and pressure are lowered (for example, to a temperature of 140 to 170° C. and a dwell time (soak) of 10 to 60 minutes and a pressure of 1 to 1.5 MPa), it is found that the resulting dielectric can exhibit lower dissipation factor.

The electrically conductive layer can be applied by laser direct structuring. Here, the composite material can comprise a laser direct structuring additive; and the laser direct structuring can comprise using a laser to irradiate the surface of the substrate, forming a track of the laser direct structuring additive, and applying a conductive metal to the track. The laser direct structuring additive can comprise a metal oxide particle (such as titanium oxide and copper chromium oxide). The laser direct structuring additive can comprise a spinel-based inorganic metal oxide particle, such as spinel copper. The metal oxide particle can be coated, for example, with a composition comprising tin and antimony (for example, 50 to 99 wt % of tin and 1 to 50 wt % of antimony, based on the total weight of the coating). The laser direct structuring additive can comprise 2 to 20 parts of the additive based on 100 parts of the composition. The irradiating can be performed with a YAG laser having a wavelength of 1,064 nanometers under an output power of 10 Watts, a frequency of 80 kilohertz, and a rate of 3 meters per second. The conductive metal can be applied using a plating process in an electroless or electrolytic plating bath comprising, for example, copper.

The electrically conductive layer can comprise at least one of stainless steel, copper, gold, silver, aluminum, zinc, tin, lead, nickel, or a transition metal. There are no particular limitations regarding the thickness of the electrically conductive layer, nor are there any limitations as to the shape, size, or texture of the surface of the electrically conductive layer. The electrically conductive layer can have a thickness of 3 to 200 micrometers, or 9 to 180 micrometers. When two or more electrically conductive layers are present, the thickness of the two layers can be the same or different. The electrically conductive layer can comprise a copper layer. Suitable electrically conductive layers include a thin layer of an electrically conductive metal such as a copper foil presently used in the formation of circuits, for example, electrodeposited or annealed copper foils.

The copper foil can have a root mean squared (RMS) roughness of less than or equal to 5 micrometers, or 0.1 to 3 micrometers, or 0.05 to 0.7 micrometers. As used herein, the roughness of the electrically conductive layer can be determined by atomic force microscopy in contact mode, reporting the Rz in micrometers calculated by determining the sum of five highest measured peaks minus the sum of the five lowest valleys and then dividing by five (JIS (Japanese Industrial Standard)-B-0601); or the roughness can be determined using white light scanning interferometry in contactless mode and is reported as Sa (arithmetical mean height), Sq (root mean square height), Sz (maximum height) height parameters in micrometers using a stitching technique to characterize treated-side surface topography and texture (ISO 25178). The copper foil can be a battery foil layer having a zinc free low profile treated side roughness, for example, having at least one of an Sa of 0.05 to 0.4 micrometers, an Sq of 0.01 to 1 micrometers, an Sz of 0.5 to 10 micrometers, or an Sdr (developed interfacial area ratio) of 0.5 to 30 percent (%).

The composite can have a dissipation loss of less than or equal to 0.005, or less than or equal to 0.003, or less than or equal to 0.0028, or 0.002 to 0.005 at 10 MHz in an anhydrous atmosphere. The composite can have a dissipation loss of less than or equal to 0.005, or loss of less than or equal to 0.0045, or 0.002 to 0.005 at 10 gigahertz (GHz) when exposed to 50% relative ambient humidity. The composite can have a permittivity of 2 to 5, or 3 to 3.5 at 10 GHz. The dissipation loss and permittivity can be measured in accordance with the “Stripline Test for Permittivity and Loss Tangent at X-Band” test method (IPC-TM-650 2.5.5.5) at a temperature of 23 to 25° C.

The composite can have a UL94 V0 rating at a thickness of 84 to 760 micrometers determined in accordance with the Underwriter's Laboratory UL 94 Standard For Safety “Tests for Flammability of Plastic Materials for Parts in Devices and Appliances.” The composite can have a peel strength to copper of 3 to 7 pounds per linear inch (pli) (0.54 to 1.25 kilograms per centimeter (kg/cm)), or 4 to 7 pli measured in accordance with IPC test method 650, 2.4.8. The glass transition temperature of the composite can be greater than or equal to 200° C. determined in accordance with the “Glass Transition Temperature and Thermal Expansion of Materials Used in High Density Interconnection (HDI) and Microvias—TMA Method” (IPC-TM-650 2.4.24.5).

A prepreg, a build-up material, a bond ply, a resin-coated electrically conductive layer, or a cover film can comprise the composite. The composite can be a non-clad or declad dielectric layer, a single clad dielectric layer, or a double clad dielectric layer. A double clad laminate has two electrically conductive layers, one on each side of the composite. A circuit material can comprise the composite. The circuit material is a type of circuit subassembly that has an electrically conductive layer, for example, copper, fixedly attached to a composite. Patterning the electrically conductive layer, for example by printing and etching, can provide the circuit. A multilayer circuit can comprise a plurality of electrically conductive layers, at least one of which contains an electrically conductive wiring pattern. Typically, multilayer circuits are formed by laminating two or more materials in proper alignment together, at least one of which contains a circuit layer, using bond plies, while applying heat or pressure. The circuit material can itself function as an antenna.

The following examples are provided to illustrate the present disclosure. The examples are merely illustrative and are not intended to limit devices made in accordance with the disclosure to the materials, conditions, or process parameters set forth herein.

### EXAMPLES

In the examples, the permittivity (Dk) and the dissipation loss (Df) (also referred to as the loss tangent) were measured in accordance with the “Stripline Test for Permittivity and Loss Tangent at X-Band” test method (IPC-TM-650 2.5.5.5) at a temperature of 23 to 25° C. The copper peel strength was determined in accordance with the “Peel strength of metallic clad laminates” test method (IPC-TM-650 2.4.8). The flame rating was determined in accordance with the Underwriter's Laboratory UL 94 Standard For Safety “Tests for Flammability of Plastic Materials for Parts in Devices and Appliances,” where a flame rating of V0 is the most difficult to achieve. Prepreg resin flow was determined in accordance with the “Resin Flow Percent of Prepreg” test method (IPC-TM-650 2.3.17). The glass transition temperature (Tg) and the coefficients of thermal expansion (CTE) in the x, y directions and in the z-direction were determined in accordance with the “Glass Transition Temperature and Thermal Expansion of Materials Used in High Density Interconnection (HDI) and Microvias—TMA Method” (IPC-TM-650 2.4.24.5).

The copper roughness was determined using atomic force microscopy in contact mode and is reported as Rz in micrometers calculated by determining the sum of five highest measured peaks minus the sum of the five lowest valleys and then dividing by five (JIS (Japanese Industrial Standard)-B-0601); or the copper roughness was determined using white light scanning interferometry in contactless mode and is reported as Sa, Sq, Sz height parameters in micrometers using a stitching technique to characterize treated-side surface topography and texture (ISO 25178).

In the examples, the terminology of a 1 ounce (oz.) copper foil refers to the thickness of the copper layer achieved when 1 ounce (29.6 milliliters) of copper is pressed flat and spread evenly over a one square foot (929 centimeters squared) area. The equivalent thickness is 1.37 mils (0.0347 millimeters). A ½ ounce copper foil correspondingly has a thickness of 0.01735 millimeters.

The components used in the examples are shown in Table 1.

TABLE 1

| | | |
|---|---|---|
| m-PPE oligomer | Noryl ^{TM} SA-9000, Methacrylate functionalized PPE, | SABIC |
| | Mn 1,500 Daltons | |
| TAIC | Triallyl isocyanurate | Evonik |
| Initiator | 2,5-dimethyl-2,5-di(t-butylperoxy)-3-hexyne | Evonik |
| Maleinized | Ricon ^{TM} 184MA6, maleinized butadiene-styrene | Cray Valley |
| copolymer | copolymer | |
| Fused silica | Spherical fused silica, grade FB-8S, median diameter | Denka |
| | of 8 micrometers | |
| Phenylsilane | Dynasylan ^{TM} 9165, phenyltriethoxysilane | Evonik |
| Fluorosilane | Dynasylan ^{TM} F-8261, | Evonik |
| | 1H, 1H, 2H, 2H-perfluorooctyltriethoxysilane | |
| Fumed silica | Aerosil ^{TM} R-711, Methacrylate functionalized | Evonik |
| | hydrophobic fumed silica having a BET surface area of | |
| | 150 m²/g | |
| Titanium dioxide | Pigment grade titanium dioxide, product 203-4, having | Ferro |
| | a D90 particle size of 1.9 micrometers | |
| Flame retardant | Saytex ^{TM} 8010; bis-pentabromophenyl ethane | Albemarle |
| Solvent | Dimethyl benzene (mixture of isomers) | Ashland |
| Glass fabric 1 | G1078S having a thickness of 45 micrometers | Shanghai Grace Fabric |
| Glass fabric 2 | G106S having a thickness of 29 micrometers | Shanghai Grace Fabric |
| Glass fabric 3 | G1027S having a thickness of 19 micrometers | Shanghai Grace Fabric |
| Cu foil 1 | Copper foil (MLS) reverse-side treated (RT) having a | Oak-Mitsui |
| | treated side roughness of 4.5 micrometers | |
| Cu foil 2 | Copper battery foil layer (BF-HFZ) having a zinc free | Circuit Foil |
| | very low profile treated side roughness of: Sa = 0.33 | Luxembourg |
| | micrometers, Sq = 0.42 micrometers, Sz = 4.4 | |
| | micrometers and a Sdr (SAR) of between 10 and 30% | |
| Cu foil 3 | Copper battery foil layer (BF-NN) having a zinc free | Circuit Foil |
| | extremely low profile treated side roughness of: | Luxembourg |
| | Sa = 0.15 micrometers, Sq = 0.19 micrometers, Sz = 1.7 | |
| | micrometers and a Sdr (SAR) of 1.2% | |

### Example 1: Preparation of Hydrophobized Fused Silica

A silane mixture of 194 grams (g) of the fluorosilane, 583 g of the phenylsilane, 179 g of distilled water, 3 g of 1.5 normal (N) hydrochloric acid, and 182 g of methylene chloride was prepared while mixing. The silane mixture was mixed for 2 hours after the silane mixture turned clear.

85.5 pounds (lbs) (38.8 kilograms (kg)) of the fused silica was added to a PK blender and spread out evenly. The blender was started and the intensifier bar turned on. The silane mixture was then filtered using an inline, 1 micrometer filter and added to the blender via the assistance of a peristaltic pump. The silane mixture was added at a constant rate over the span of 7 minutes. After the silane mixture was added, the intensifier bar was left on for 5 minutes, after which the blender and the intensifier bar were turned off. The outside of the blender was tapped with a mallet to help remove the material from the inner surface of the blender, the blender was rotated 180 degrees and tapped again. The blender was then run for an additional 10 minutes to form the hydrophobized fused silica.

The relative hydrophobicity of the hydrophobized fused silica was confirmed by mixing with water under agitation, where the hydrophobized fused silica did not wet-out.

### Example 2: Preparation of the Thermosetting Composition

A thermosetting composition was formed as described in Table 2 for use in preparing prepregs of woven glass reinforced composites.

TABLE 2

| Material | wt % | Solids (wt %) |
|---|---|---|
| Hydrophobized fused silica of Ex. 1 | 33.1 | 42.4 |
| 50 wt % m-PPE oligomer in solvent | 37.8 | 24.2 |
| TAIC | 14.2 | 18.2 |
| Initiator | 0.8 | 1.0 |
| Maleinized copolymer | 1.4 | 1.8 |
| Flame retardant | 7.6 | 9.7 |
| Fumed silica | 1.5 | 1.9 |
| Titanium dioxide | 0.5 | 0.7 |
| Solvent | 3.1 | — |

### Examples 3-5: Formation of Prepregs of the Woven Glass Reinforced Composites

The prepregs were formed by treating glass fabrics 1, 2, or 3 with the thermosetting composition of Example 2. As desired, single-ply prepregs or stacks of prepregs were laminated along with ½ ounce copper foils located on either side of the prepregs using a typical epoxy cure cycle of 90 minutes at 185° C. at a pressure of 1.7 megapascal (MPa). The respective properties of the resultant laminates are shown in Table 3. In the table, the wt % of the dielectric resin concentration is based on the total weight of the cured composite including the glass fabric.

TABLE 3

| Example | 3 | 4 | 5 |
|---|---|---|---|
| Glass fabric | 1 | 2 | 3 |
| Dielectric resin concentration (wt %) | 76.8 | 81.6 | 83.2 |
| Single ply prepreg thickness (micrometers) | 133 | 76 | 69 |
| Number of plies | 6 | 10 | 10 |
| Post-lamination composite thickness (micrometers) | 798 | 759 | 688 |
| Permittivity, Dk, at 10 GHz | 3.43 | 3.31 | 3.20 |
| Dissipation loss, Df, at 10 GHz | 0.0042 | 0.0040 | 0.0042 |
| Glass transition temperature, Tg (° C.) | 219 | 222 | 236 |
| CTE-x/y (ppm/° C.) (50 to 150° C.) | 17 | 21 | 23 |
| CTE-z (ppm/° C.) (50 to 150° C.) | 40 | 43 | 46 |

Table 3 shows that the composites formed from the present thermosetting composition exhibit a permittivity of 3.0 to 3.5 at 10 GHz and a dissipation loss of less than 0.005 at 10 GHz. The composites also exhibited good Tg values and good CTE values in the x, y, and z-directions.

Composites ranging in thickness from 76 to 798 micrometers, derived from the prepreg plies associated with Examples 3-5, all exhibited a flame rating of UL94 V0.

### Examples 6-14: Formation of Copper Clad Laminates Using a Typical Epoxy Cure Cycle

Composites were prepared (Examples 6-8, 9-11, and 12-14) using prepreg plies in accordance with Examples 3, 4, and 5, respectively. Stacks of each of the prepregs along with ½ ounce copper foils located on either side of the prepreg stacks were then laminated using the typical epoxy cure cycle of 90 minutes at 185° C. at a pressure of 1.7 megapascal (MPa). In half of the examples, the copper clad laminates were tested for peel strength as-received (AR) and in the other half of the examples, the copper clad laminates were tested for peel strength after being subjected to a thermal stress (AS) by heating to a temperature of 288° C. for 10 seconds. The peel strength results for each copper clad laminate (AR and AS) are shown in Table 4.

TABLE 4
Glass fabric 1, thermosetting mixture 76.8 wt %, dielectric laminate thickness 228 micrometers

| Example | 6 | 7 | 8 |
|---|---|---|---|
| Copper foil | 1 | 2 | 3 |
| Peel strength (pli (kg/cm)), Copper foil as received | 4.3 (0.77) | 3.7 (0.66) | — |
| Peel strength (pli (kg/cm)), Copper foil thermal | 4.3 (0.77) | 3.5 (0.63) | — |
| stressed | | | |

Glass fabric 2, thermosetting mixture 81.6 wt %, dielectric laminate thickness 157 micrometers

| Example | 9 | 10 | 11 |
|---|---|---|---|
| Copper foil | 1 | 2 | 3 |
| Peel strength (pli (kg/cm)), Copper foil as received | 5.0 (0.89) | 4.8 (0.86) | — |
| Peel strength (pli (kg/cm)), Copper foil thermal | 4.5 (0.80) | 4.8 (0.86) | — |
| stressed | | | |

Glass fabric 3, thermosetting mixture 83.2 wt %, dielectric laminate thickness 690 micrometers

| Example | 12 | 13 | 14 |
|---|---|---|---|
| Copper foil | 1 | 2 | 3 |
| Peel strength (pli (kg/cm)), Copper foil as received | — | 4.6 (0.82) | 3.4 (0.61) |
| Peel strength (pli (kg/cm)), Copper foil thermal | — | 4.7 (0.84) | 3.1 (0.55) |
| stressed | | | |

Table 4 shows that all of the laminates exhibited a good peel strength with the copper foil of greater than or equal to 3 pli (0.54 kg/cm).

### Examples 15-18: Formation of Copper Clad Laminates Using a Modified Cure Cycle

A prepreg was formed by treating the thermosetting mixture of Example 1 onto glass fabric 2. The dielectric resin was present in amount of 81.6 wt % and the prepreg had a ply thickness of 84 micrometers. Two and seven-layer stacks of the prepreg with copper foil layers located on either side were then laminated using a modified cure cycle as shown in Table 5. Copper clad laminates with dielectric thicknesses of 152 and 533 micrometers were tested for peel strength using as-received (AR) copper and the results are shown in Table 6.

TABLE 5

| Parameter | Setting |
|---|---|
| Temperature Ramp Rate (° C./min) | 5.6 |
| Temperature to Initiate Pressure Ramp Rate (° C.) | 135 |
| Pressure Ramp Rate (MPa/minute) | 2.8 |
| Applied Pressure (MPa) | 1.4 |
| Dwell Temperature (° C.) | 163 |
| Dwell Time (minutes) | 10 |
| Resin Flow Percent of Prepreg (%) | 34.1 |

TABLE 6

| Example | 15 | 16 | 17 | 18 |
|---|---|---|---|---|
| Copper foil | 2 | 2 | 3 | 3 |
| Copper foil thickness (ounces) | ½ | 1 | ½ | 1 |
| Dk (10 GHz) | 3.35 ± 0.05 | 3.34 ± 0.07 | 3.38 ± 0.04 | 3.37 ± 0.02 |
| Df (10 GHz) | 0.0027 | 0.0027 | 0.0027 | 0.0026 |
| Peel strength, 152 μm (pli) (kg/cm) | 3.4 ± 0.4 (0.61) | 5.3 ± 0.5 (0.95) | 5.2 ± 0.1 (0.93) | 5.1 ± 0.4 (0.91) |
| Peel strength, 533 μm (pli) (kg/cm) | 3.4 ± 0.1 (0.61) | 4.9 ± 0.2 (0.88) | 5.9 ± 0.2 (1.05) | 6.6 ± 0.3 (1.18) |

Table 6 shows that not only did of the laminates of Examples 15-18 exhibit a good peel strength with the copper foil of greater than or equal to 3 pli (0.54 kg/cm), but they were also able to achieve extremely low dissipation loss values of less than 0.003 at 10 GHz.

### Examples 19-25: Comparison to Commercially Available Products

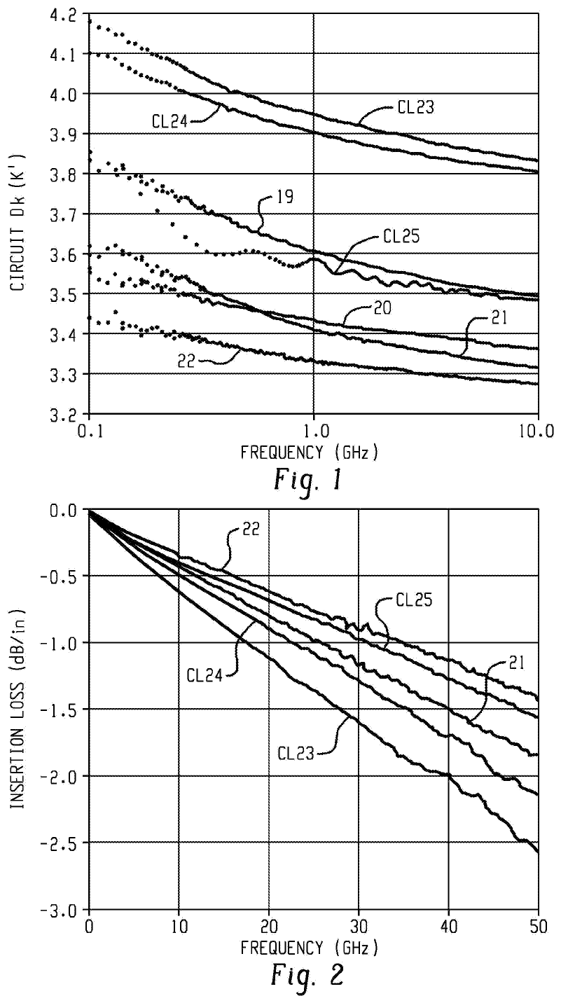

Four copper clad laminates were prepared using a standard epoxy lamination cycle, where the copper foil types and composite dielectric thicknesses are shown in Table 7. Permittivity of Examples 19-22 and insertion loss of Examples 21-22 were compared to a commercially available laminate (CL) laminated with different copper foils: ED (CL23), H-VLP (CL24) and H-VLP (CL25). As used herein, H-VLP refers to the copper foil being a hyper-very-low-profile with an Rz of 2 to 3 micrometers on both sides and ED refers to the copper foil being electrodeposited. The permittivity and insertion loss values with frequency are shown in FIG. 1 and FIG. 2, respectively.

TABLE 7

| | Composite Dielectric | | Circuit Dk (K’) | Insertion Loss at |
|---|---|---|---|---|
| Example | Thickness (μm) | Copper Foil Type | at 10 GHz | 50 GHz (dB/in) |
| 19 | 63 | ½ oz. MLS-RT | 3.484 | — |
| 20 | 63 | ½ oz. BF-NN | 3.315 | — |
| 21 | 128 | ½ oz. MLS-RT | 3.362 | −1.81 |
| 22 | 128 | ½ oz. BF-NN | 3.273 | −1.39 |
| CL23 | 102 | ½ oz. H-VLP | 3.828 | −2.57 |
| CL24 | 102 | ½ oz. H-VLP | 3.803 | −2.14 |
| CL25 | 102 | ½ oz. H-VLP | 3.482 | −1.56 |

FIG. 1 illustrates that the laminates of Examples 20, 21, and 22 all had lower permittivity values as compared to all of the commercially available laminated tested and the laminate of Example 19 had lower permittivity values as compared to the commercially available laminates 23 and 24.

FIG. 2 illustrates that the present laminates can achieve improved insertion loss values as compared to the commercial products. For example, the laminate of Example 21 had an improved insertion loss as compared to the commercially available laminates 23 and 24 the laminate of Example 22 having the battery foil NN had an improved insertion loss over commercially available laminate 25.

### Examples 23-29: Effect of the Block Copolymer

Seven copper clad laminates were prepared using either lamination cycle (1) having a lamination temperature of 218° C. and a lamination pressure of 2 MPa for 120 minutes or the standard epoxy lamination cycle (2) described above; and the ½ ounce Cu foil 1. The amounts of the components are in wt % based on the total weight of the solids in the thermosetting composition and the resin amount is in wt % based on the total weight of the prepreg.

TABLE 8

| Material | 23 | 24 | 25 | 26 | 27 | 28 | 29 |
|---|---|---|---|---|---|---|---|
| Hydrophobized | 45.4 | 43.6 | 43.4 | 43.4 | 43.4 | 43.4 | 43.4 |
| fused silica of | | | | | | | |
| Ex. 1 | | | | | | | |
| 50 wt % m-PPE | 25.9 | 24.9 | 24.8 | 24.8 | 24.8 | 24.8 | 24.8 |
| oligomer in | | | | | | | |
| solvent | | | | | | | |
| TAIC | 19.5 | 18.7 | 18.6 | 18.6 | 18.6 | 18.6 | 18.6 |
| Initiator | 0.3 | 0.2 | 0.2 | 0.2 | 0.2 | 0.2 | 0.2 |
| Maleinized | 0.0 | 1.2 | 1.9 | 1.9 | 1.9 | 1.9 | 1.9 |
| copolymer | | | | | | | |
| Flame retardant | 7.8 | 10.0 | 9.9 | 9.9 | 9.9 | 9.9 | 9.9 |
| Fumed silica | 0.4* | 0.5 | 0.5 | 0.5 | 0.5 | 0.5 | 0.5 |
| Titanium dioxide | 0.8 | 0.7 | 0.7 | 0.7 | 0.7 | 0.7 | 0.7 |
| Glass fabric | 1 | 1 | 1 | 1 | 1 | 1 | 2 |
| Resin amount | 79.8% | 79.7% | 79.6% | 80.2% | 76.8% | 82.2% | 81.6% |
| Lamination cycle | 1 | 1 | 1 | 2 | 2 | 2 | 2 |
| Peel strength (pli | 2.3 | 4.1 | 4.2 | 4.8 | 4.3 | 4.6 | 5.0 |
| (kg/cm)), Copper | (0.41) | (0.73) | (0.75) | (0.86) | (0.77) | (0.82) | (0.89) |
| foil as received | | | | | | | |
| Peel strength (pli | 2.1 | 3.6 | 4.0 | 4.3 | 4.3 | 4.6 | 4.5 |
| (kg/cm)), Copper | (0.38) | (0.64) | (0.71) | (0.77) | (0.77) | (0.82) | (0.80) |
| foil thermal | | | | | | | |
| stressed | | | | | | | |
| Df (10 GHz) | 0.0029 | 0.0029 | 0.0029 | 0.0028 | 0.0028 | 0.0029 | 0.0030 |

*The fumed silica of Example 23 was Aerosil ™ R 972

Table 8 shows that the laminate of Example 24 that comprises only 1.2 wt % of the block copolymer has a peel strength of 4.1 kg/cm, almost two times that of Example 23 comprising 0 wt % of the block copolymer. Example 25 and Example 26 shows that merely by reducing the lamination temperature, time and pressure, the peel strength increased from 4.2 kg/cm to 4.8 kg/cm. Examples 26-29 show that by varying the resin amount and glass fabric type also affect the peel strength.

Set forth below are non-limiting aspects of the present disclosure.

Aspect 1: A dielectric composite comprising: a thermoset derived from a functionalized poly(arylene ether), a triallyl (iso)cyanurate, and a functionalized block copolymer; a hydrophobized fused silica; and a fabric.

Aspect 2: The composite of Aspect 1, wherein the composite has at least one of a dissipation loss of less than or equal to 0.005, or less than or equal to 0.003, or less than or equal to 0.0028 at 10 GHz when exposed to 50% relative ambient humidity; a UL94 V0 rating at a thickness of 84 to 760 μm; or a peel strength to copper of 0.54 to 1.25 kg/cm.

Aspect 3: The composite of any one or more of the preceding aspects, wherein the functionalized poly(arylene ether) has a number average molecular weight of 500 to 3,000 Daltons, or 1,000 to 2,000 Daltons based on polystyrene standards.

Aspect 4: The composite of any one or more of the preceding aspects, wherein the thermoset was derived from a thermosetting composition comprising 40 to 60 wt % of the functionalized poly(arylene ether) based on the total weight of the thermosetting components.

Aspect 5: The composite of any one or more of the preceding aspects, wherein the composite comprises 25 to 60 wt %, or 35 to 50 wt % of the thermoset based on the total weight of the composite minus the fabric.

Aspect 6: The composite of any one or more of the preceding aspects, wherein the thermoset was derived from a thermosetting composition comprising 0.1 to 10 wt %, or 0.5 to 5 wt %, or 2 to 5 wt % of the functionalized block copolymer based on the total weight of the thermosetting components.

Aspect 7: The composite of any one or more of the preceding aspects, wherein at least one of the functionalized block copolymer comprises a maleinized styrenic block copolymer or the functionalized poly(arylene ether) comprises a methacrylate functionalized poly(arylene ether).

Aspect 8: The composite of any one or more of the preceding aspects, wherein the functionalized styrenic block copolymer has at least one of a carboxylic acid number of 10 to 50, or 28 to 40 meq KOH/g; a number average molecular weight of 1,000 to 20,000 Da, or 8,000 to 15,000 Da based on polystyrene standards; and a styrene content of 10 to 50 wt %, or 15 to 30 wt % based on the total weight of the functionalized styrenic block copolymer.

Aspect 9: The composite of any one or more of the preceding aspects, wherein the composite comprises 20 to 60 wt %, or 35 to 50 wt %, 35 to 40 wt % of the hydrophobized fused silica based on the total weight of the composite minus the fabric.

Aspect 10: The composite of any one or more of the preceding aspects, wherein the hydrophobized fused silica comprises a surface treatment derived from at least one of a phenyl silane or a fluorosilane; wherein the hydrophobized fused silica has a D90 particles size of 1 to 20 micrometers, or 5 to 15 micrometers.

Aspect 11: The composite of any one or more of the preceding aspects, further comprising a ceramic filler other than the hydrophobized fused silica, wherein the ceramic filler optionally comprises at least one of fumed silica, titanium dioxide, barium titanate, strontium titanate, corundum, wollastonite, Ba₂Ti₉O₂₀, hollow ceramic spheres, boron nitride, aluminum nitride, silicon carbide, beryllia, alumina, alumina trihydrate, magnesia, mica, talc, nanoclay, or magnesium hydroxide.

Aspect 12: The composite of Aspect 11, wherein the ceramic filler comprises a hydrophobic fumed silica.

Aspect 13: The composite of Aspect 12, wherein the hydrophobic fumed silica comprises a methacrylate functionalized hydrophobic fumed silica.

Aspect 14: The composite of any one or more of Aspects 12 to 13, wherein the composite comprises 0.1 to 5 wt %, or 1 to 5 wt % of the hydrophobic fumed silica based on the total weight of the composite minus the fabric.

Aspect 15: The composite of any one or more of Aspects 12 to 14, wherein the hydrophobic fumed silica comprises a surface treatment derived from 2-propenoic acid, 2-methyl-, 3-(trimethoxysilyl)propylester; and wherein the hydrophobic fumed silica has a BET surface area of 100 to 200 m²/g, or 145 to 155 m²/g.

Aspect 16: The composite of any one or more of Aspect 11 to 15, wherein the ceramic filler comprises titanium dioxide.

Aspect 17: The composite of Aspect 16, wherein the composite comprises 0.1 to 10 wt %, or 0.1 to 5 wt % of the titanium dioxide based on the total weight of the composite minus the optional fabric.

Aspect 18: The composite of any one or more of Aspects 11 to 17, wherein the ceramic filler has a D90 particle size of 0.5 to 10, or 0.5 to 5 micrometers.

Aspect 19: The composite of any one or more of Aspects 11 to 18, wherein the ceramic filler comprises a hydrophobic fumed silica and titanium dioxide and a weight ratio of the hydrophobic fumed silica to the titanium dioxide is 1:2 to 2:1.

Aspect 20: The composite of any one or more of the preceding aspects, further comprising a flame retardant.

Aspect 21: The composite of Aspect 20, wherein the composite comprises 1 to 15 wt %, or 5 to 10 wt % of the flame retardant based on the total weight of the composite minus the fabric.

Aspect 22: The composite of any one or more of the preceding aspects, wherein the composite comprises the fabric in an amount of 5 to 40 wt %, or 15 to 25 wt % based on the total weight of the composite.

Aspect 23: The composite of any one or more of the preceding aspects, wherein the fabric comprises at least one of L glass fibers or quartz fibers, wherein the fabric is a spread-weave fabric that is present in an amount of 5 to 40 wt %, or 15 to 25 wt % based on the total weight of the composite.

Aspect 24: The composite of any one or more of the preceding aspects, wherein the composite is a prepreg having a thickness of 1 to 1,000 micrometers; and wherein the thermoset is only partially cured.

Aspect 25: The composite of any one or more of the preceding aspects, wherein the composite comprises: 25 to 60 wt % of thermoset derived from a functionalized poly(phenylene ether), a triallyl isocyanurate, and of a maleinized styrenic block copolymer that comprises styrenic blocks and blocks derived from a conjugated diene; 20 to 60 wt % of the hydrophobized fused silica; 0 to 5 wt %, or 0.1 to 5 wt % of a hydrophobic fumed silica, wherein the hydrophobic fumed silica comprises a methacrylate functionalized hydrophobic fumed silica; 0 to 10 wt %, or 0.1 to 10 wt % of a titanium dioxide, wherein the titanium dioxide has a D90 particle size of 0.5 to 10 micrometers, or 0.5 to 5 micrometers; 0 to 15 wt %, or 1 to 15 wt % of a flame retardant; all based on the total weight of the composite minus the fabric and 5 to 40 wt % of a glass fabric based on the total weight of the composite.

Aspect 26: A circuit material comprising the composite of any one or more of the preceding aspects and at least one electrically conductive layer.

Aspect 27: The circuit material of Aspect 26, wherein the at least one electrically conductive layer has an Rz surface roughness of less than or equal to 5 micrometers, or 0.1 to 3 micrometers.

Aspect 28: A method of making the composite of any one or more of Aspects 1 to 25, comprising forming a thermosetting composition comprising the methacrylate functionalized poly(arylene ether), the triallyl (iso)cyanurate, the functionalized block copolymer, the hydrophobized fused silica, an initiator, and a solvent; coating the fabric with the thermosetting composition; at least partially curing the thermosetting composition to form a prepreg.

Aspect 29: The method of Aspect 28, further comprising laminating the prepreg, wherein the laminating occurs at 100 to 180° C. and 1 to 1.5 MPa for 5 to 50 min.

Aspect 30: The method of any one or more of Aspects 28 to 29, further comprising pre-treating a fused silica a hydrophobic silane to form the hydrophobized fused silica prior to forming the thermosetting composition.

The compositions, methods, and articles can alternatively comprise, consist of, or consist essentially of, any appropriate materials, steps, or components herein disclosed. The compositions, methods, and articles can additionally, or alternatively, be formulated so as to be devoid, or substantially free, of any materials (or species), steps, or components, that are otherwise not necessary to the achievement of the function or objectives of the compositions, methods, and articles.

As used herein, “a,” “an,” “the,” and “at least one” do not denote a limitation of quantity, and are intended to cover both the singular and plural, unless the context clearly indicates otherwise. For example, “an element” has the same meaning as “at least one element,” unless the context clearly indicates otherwise. The term “combination” is inclusive of blends, mixtures, alloys, reaction products, and the like. Also, “at least one of” means that the list is inclusive of each element individually, as well as combinations of two or more elements of the list, and combinations of at least one element of the list with like elements not named.

The term “or” means “and/or” unless clearly indicated otherwise by context. Reference throughout the specification to “an aspect”, “another aspect”, “some aspects”, and so forth, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects. The terms “first,” “second,” and the like as used herein do not denote any order, quantity, or importance, but rather are used to distinguish one element from another. Unless defined otherwise, technical and scientific terms used herein have the same meaning as is commonly understood by one of skill in the art to which this disclosure belongs.

Unless specified to the contrary herein, all test standards are the most recent standard in effect as of the filing date of this application, or, if priority is claimed, the filing date of the earliest priority application in which the test standard appears. The endpoints of all ranges directed to the same component or property are inclusive of the endpoints, are independently combinable, and include all intermediate points and ranges. For example, ranges of “up to 25 wt %, or 5 to 20 wt %” is inclusive of the endpoints and all intermediate values of the ranges of “5 to 25 wt %,” such as 10 to 23 wt %, etc.

Compounds are described using standard nomenclature. For example, any position not substituted by any indicated group is understood to have its valency filled by a bond as indicated, or a hydrogen atom. A dash (“-”) that is not between two letters or symbols is used to indicate a point of attachment for a substituent. For example, —CHO is attached through carbon of the carbonyl group. As used herein, the term “(meth)acryl” encompasses both acryl and methacryl groups. As used herein, the term “(iso)cyanurate” encompasses both cyanurate and isocyanurate groups.

All cited patents, patent applications, and other references are incorporated herein by reference in their entirety. However, if a term in the present application contradicts or conflicts with a term in the incorporated reference, the term from the present application takes precedence over the conflicting term from the incorporated reference. While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

What is claimed is:

1. A dielectric composite comprising:
a thermoset derived from a functionalized poly(arylene ether), a triallyl (iso)cyanurate, and a functionalized block copolymer;
a hydrophobized fused silica; and
a reinforcing fabric.

2. The dielectric composite of claim 1, wherein the dielectric composite has at least one of
a dissipation loss of less than or equal to 0.005 at 10 gigahertz when exposed to 50 percent relative ambient humidity;
a UL94 V0 rating at a thickness of 84 to 760 micrometers; or
a peel strength to copper of 0.54 to 1.25 kilograms per centimeter measured in accordance with IPC test method 650, 2.4.8.

3. The dielectric composite of claim 1, wherein the functionalized poly(arylene ether) has a number average molecular weight of 500 to 3,000 Daltons based on polystyrene standards.

4. The dielectric composite of claim 1, wherein the thermoset was derived from a thermosetting composition comprising 40 to 60 weight percent of the functionalized poly(arylene ether) based on the total weight of the thermosetting components.

5. The dielectric composite of claim 1, wherein the dielectric composite comprises 25 to 60 weight percent of the thermoset based on the total weight of the dielectric composite minus the reinforcing fabric.

6. The dielectric composite of claim 1, wherein the thermoset was derived from a thermosetting composition comprising 0.1 to 10 wt % of the functionalized block copolymer based on the total weight of the thermosetting components.

7. The dielectric composite of claim 1, wherein at least one of the functionalized block copolymer comprises a maleinized styrenic block copolymer or the functionalized poly(arylene ether) comprises a methacrylate functionalized poly(arylene ether).

8. The dielectric composite of claim 1, wherein the dielectric composite comprises 20 to 60 weight percent of the hydrophobized fused silica based on the total weight of the dielectric composite minus the reinforcing fabric.

9. The dielectric composite of claim 1, wherein the hydrophobized fused silica comprises a surface treatment derived from at least one of a phenyl silane or a fluorosilane; wherein the hydrophobized fused silica has a D90 particles size of 1 to 20 micrometers.

10. The dielectric composite of claim 1, further comprising at least one of a hydrophobic fumed silica or titanium dioxide.

11. The dielectric composite of claim 1, wherein the dielectric composite comprises a hydrophobic fumed silica and titanium dioxide and a weight ratio of the hydrophobic fumed silica to the titanium dioxide is 1:2 to 2:1.

12. The dielectric composite of claim 1, wherein the dielectric composite further comprises 1 to 15 weight percent of a flame retardant based on the total weight of the dielectric composite minus the reinforcing fabric.

13. The dielectric composite of claim 1, wherein the dielectric composite comprises the reinforcing fabric in an amount of 5 to 40 weight percent based on the total weight of the dielectric composite.

14. The dielectric composite of claim 1, wherein the reinforcing fabric comprises at least one of L glass fibers or quartz fibers, wherein the reinforcing fabric is a spread-weave reinforcing fabric that is present in an amount of 5 to 40 weight percent on the total weight of the dielectric composite.

15. The dielectric composite of claim 1, wherein the dielectric composite is a prepreg having a thickness of 1 to 1,000 micrometers; and wherein the thermoset is only partially cured.

16. A circuit material comprising the dielectric composite of claim 1 and at least one electrically conductive layer.

17. The circuit material of claim 16, wherein the at least one electrically conductive layer has an Rz surface roughness of less than or equal to 5 micrometers.

18. A dielectric composite comprising:
25 to 60 weight percent of a thermoset derived from a functionalized poly(phenylene ether)a triallyl isocyanurate, and a maleinized styrenic block copolymer that comprises styrenic blocks and blocks derived from a conjugated diene;
20 to 60 weight percent of the hydrophobized fused silica;
0.1 to 5 weight percent of a hydrophobic fumed silica, wherein the hydrophobic fumed silica comprises a methacrylate functionalized hydrophobic fumed silica;
0.1 to 10 weight percent of a titanium dioxide, wherein the titanium dioxide has a D90 particle size of 0.5 to 10 micrometers, or 0.5 to 5 micrometers;
1 to 15 weight percent of a flame retardant;
all based on the total weight of the dielectric composite minus the reinforcing fabric and
5 to 40 weight percent of a glass fabric based on the total weight of the dielectric composite.

19. A method of making a dielectric composite, comprising
forming a thermosetting composition comprising a methacrylate functionalized poly(arylene ether), a triallyl (iso)cyanurate, a functionalized block copolymer, a hydrophobized fused silica, an initiator, and a solvent;
coating a reinforcing fabric with the thermosetting composition;
at least partially curing the thermosetting composition to form a prepreg; and
optionally laminating the prepreg and the at least one electrically conductive layer to form the circuit material.

20. The method of claim 19, further comprising pre-treating a fused silica a hydrophobic silane to form the hydrophobized fused silica prior to forming the thermosetting composition.
